(19) United States
(12) Patent Application Publication
(10) Pub. No.: US 2008/0128675 A1
(43) Pub. Date: Jun. 5, 2008

(54) Phase change memory cell having a tapered microtrench

(76) Inventors: Michele Magistretti, Gessate (MI) (IT); Pietro Petruzza, Pessano Con Bornago (MI) (IT); Giovanni Mazzone, Villasanta (MI) (IT); Fabio Pellizzer, Follina (TV) (IT); Silvio Cristofalo, Pessano Con Bornago (MI) (IT)

Correspondence Address: TROP PRUNER & HU, PC, 1616 S. VOSS ROAD, SUITE 750, HOUSTON, TX, 77057-2631, US

(21) Appl. No.: 11/606,800

(22) Filed: Nov. 30, 2006

(51) Int. Cl. H01L 45/00

(52) U.S. Cl. 257/4; 438/104; 257/E45.002

(57) ABSTRACT

A phase change memory includes a cup-shaped heater element formed above a body. A tapered phase change region is formed on the cup-shaped heater element. The cup-shaped heater element is formed by depositing a stop layer of a first dielectric material over the body. A first sacrificial layer is deposited over the stop layer, the first sacrificial layer being of a second dielectric material that can be etched selectively with respect to the first dielectric material. An opening is etched in the first sacrificial layer and the stop layer. A heating layer is formed in the opening. The opening is filled with a filling material to obtain a structure having a cup-shaped heating region formed in the stop layer and excess portions extending over said stop layer. The excess portions by an etch selective with respect to the first dielectric material are removed.

### BACKGROUND

This relates generally to phase change memories using chalcogenide alloys.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

For the understanding of the present invention, a preferred embodiment is now described, purely as a non-limitative example, with reference to the enclosed drawings, wherein:

FIG. 1 is a cross-section through a semiconductor wafer taken generally along the line I-I in FIG. 2, at an initial step of a manufacturing process according to an embodiment of the invention;

FIG. 2 shows the layout of some masks used for forming the structure of FIG. 1;

FIG. 3 is a cross-section of the wafer of FIG. 1, taken along line III-III of FIG. 2;

FIGS. 4-12 are enlarged details of the wafer of FIG. 3 in subsequent manufacturing steps;

FIG. 13 is a cross-section through the wafer of FIG. 4, at a final manufacturing step; and

FIG. 14 is a system depiction for another embodiment of the invention.

### DETAILED DESCRIPTION

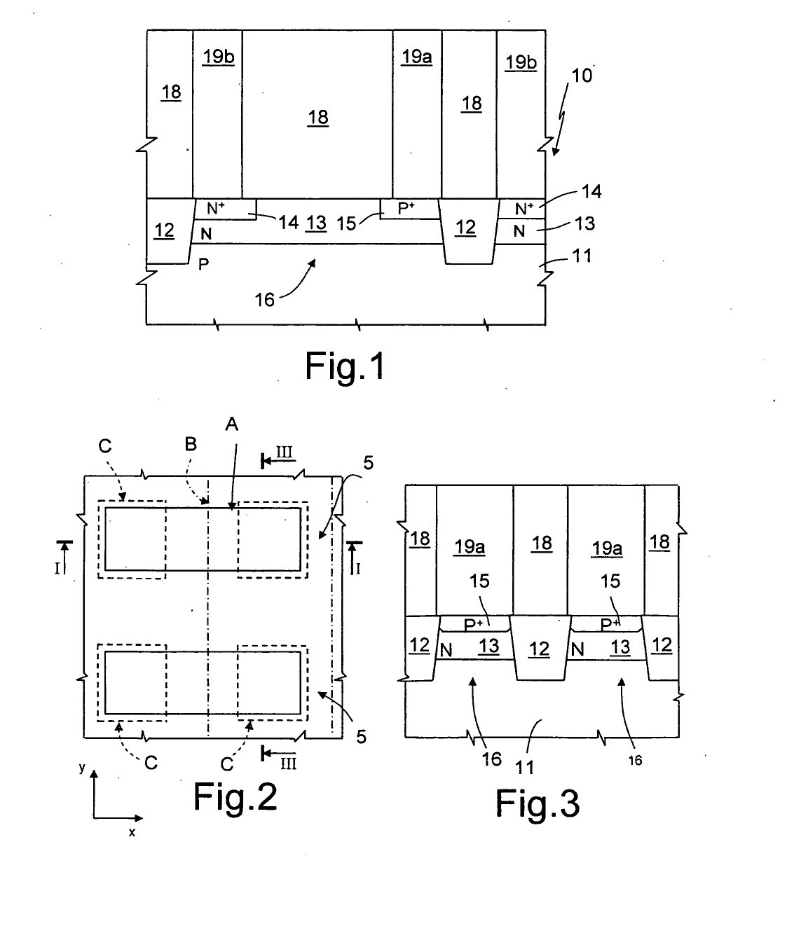

With reference to FIG. 1, initially a wafer 10 comprising a P-type substrate 11 may be subjected to standard front end manufacturing steps. In particular, insolation regions 12 formed in the substrate 11 delimit active areas 16 and then N-type base regions 13 are implanted in one embodiment.

Next, a dielectric layer 18 may be deposited and planarized and openings may be formed in the dielectric layer 18 above the base regions 13 and emitter regions 15. Using two dedicated masks in one embodiment, base contact regions 14 of N⁺-type and emitter regions 15 of P⁺-type are implanted self-aligned with the openings. Then the openings in the dielectric layer 18 may be covered by a barrier layer, for example a Ti/TiN layer, before being filled with tungsten to form base contacts 19b and emitter contacts 19a. The base contacts 19b are thus in direct electrical contact with the base regions 13, and the emitter contacts 19a are in direct electrical contact with the emitter regions 15 in one embodiment. The base regions 13, base contact regions 14 and emitter regions 15 form selection elements for memory cells.

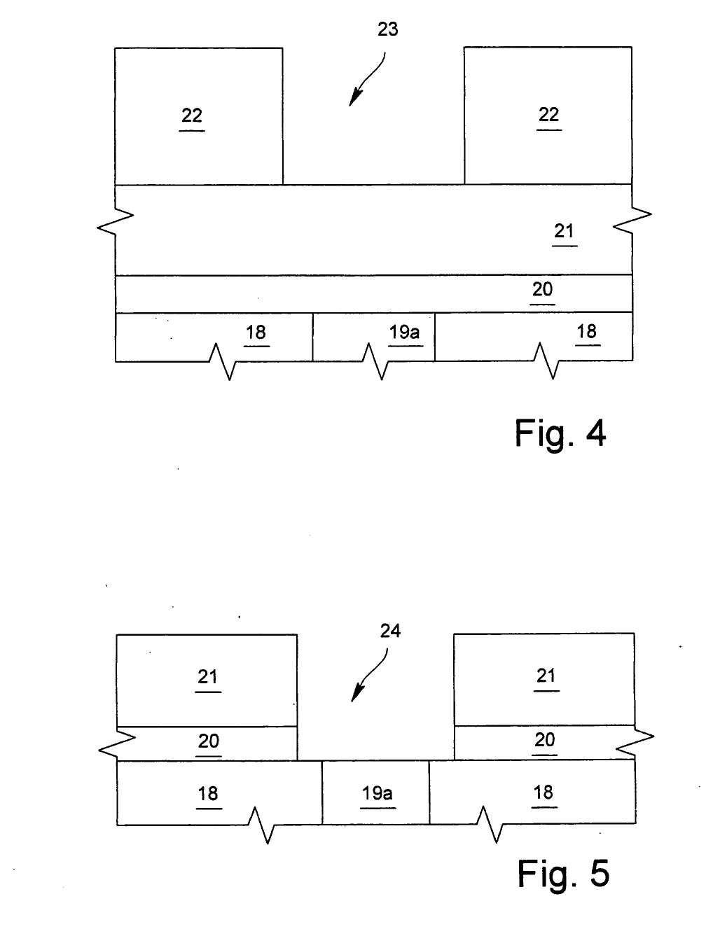

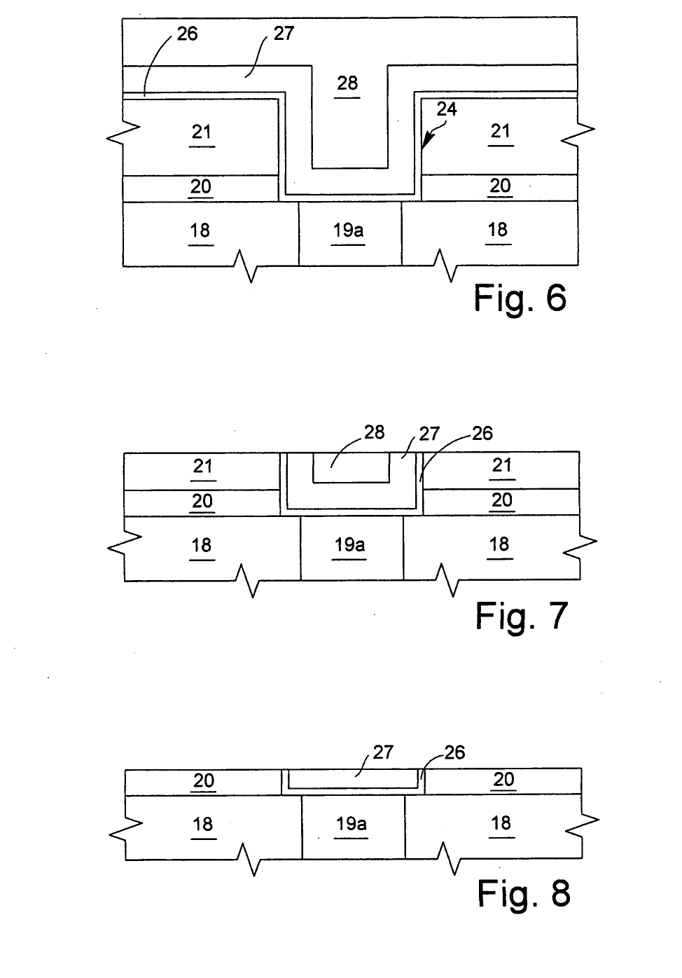

FIG. 2 shows the layout of some masks used for forming the structure of FIGS. 1 and 3 to obtain a pair of memory cells 5 that are adjacent in a direction Y perpendicular to the sectional plane of FIG. 1 (direction X). In particular, FIG. 2 shows a mask A used for defining the active areas 16, a mask B used for implanting the emitter regions 15, and a mask C used for forming the openings where the base contacts 19b and the emitter contacts 19a are to be formed.

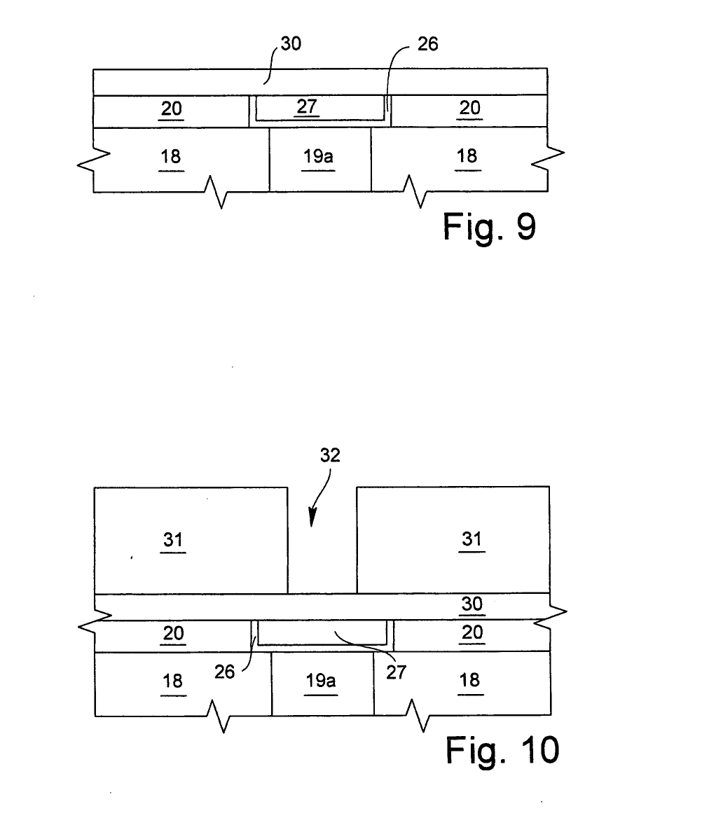

Next, as shown in the enlarged detail of FIG. 4, an etch stop layer 20 and a first sacrificial layer 21 may be deposited. Stop layer 20 is a dielectric material, for example nitride (SiN) with a thickness between 10 and 100 nm, preferably 60 nm, and the second sacrificial layer 21 is a dielectric material, for example oxide having a higher thickness than the stop layer 600-1500 nm, preferably 100 nm. Advantageously, stop layer and sacrificial layer 21 are of two different materials that can be etched selectively, as explained in further detail later on.

Then a resist mask 22 is formed so as to have windows 23 vertically aligned with the emitter contacts 19a in one embodiment. Using resist mask 22, the stop layer 20 and the first sacrificial layer 21 may be etched at the windows 23 as shown in FIG. 5. In one embodiment, a dry process may be used, wherein the first sacrificial layer 21 is removed through a non-selective process, while the stop layer 20 is removed using a selective process that ends on the dielectric layer 18 and the emitter contacts 19a. Thus, openings 24 having dimensions dictated by the lithographic process are formed in layers 20, 21, and are, for example, circular. The resulting structure, after removing the resist mask 22, is shown in FIG. 5.

Next, as shown in FIG. 6, a heating layer 26, a sealing layer 27 and a second sacrificial layer 28 may be deposited. The heating layer 26 is for example TiSiN, TiAlN, TiSiC or WN with a thickness of 2-20 nm, preferably 5 nm. The sealing layer 27 is preferably of the same material as the stop layer 20, e.g. nitride, and has the same thickness except reduced by the thickness of the heating layer 26. The second sacrificial layer 28 is of a material that is selectively etched with respect to stop layer 20 and sealing layer 27. The heating layer 26 and the sealing layer 27 conformally coat the walls and bottom of the openings 24. The openings 24 may be completely filled by second sacrificial layer 28.

Then, in FIG. 7, a first planarization step is performed. In particular, the excess portions of the second sacrificial layer 28, the sealing layer 27 and the heating layer 26 (outside the openings 24), as well as a portion of the first sacrificial layer 21 are etched by CMP (“Chemical Mechanical Polishing”), using a first non-selective slurry (e.g. a silica non-selective slurry).

Then, in FIG. 8, a second planarization step is performed. In particular, the first and second sacrificial layers 21, 28 are removed by CMP using a second slurry, selective with respect to stop layer 20 as, for example, nitride (e.g., ceria high selective slurry), so that the planarization ends automatically on the stop and sealing layers 20, 27. If the stop layer 20 and the sealing layer 27 have substantially equal thicknesses, the wafer 10 has a very planar surface with controlled, constant dimensions.

The remaining portions of the heating layer 26 thus form a cup-shaped region which, from above, has a ring-like or an elongated shape (e.g., rectangular or oval) and is both externally and internally surrounded by nitride (stop layer 20 and sealing layer 27).

Next, in FIG. 9, a mold layer 30, having a thickness of 40-90 nm, for example, may be deposited. The mold layer 30 may be of a material that can be etched selectively with respect to the material of the sealing layer 27 and the cup-shaped layer 26, preferably oxide or SiON. A photoresist mask 31 is then deposited on the mold layer 30.

As illustrated in FIG. 10, the photoresist mask 31 has apertures 32. The apertures 32 may extend in a plane perpendicular to the drawing and vertically cross the cup shaped regions 26. The width of the apertures 32 may be about 80-120 nm, i.e. greater than the minimum dimension obtainable through optical UV lithography.

Subsequently, in FIG. 11, the mold layer 30 may be etched through the apertures 32, so as to open microtrenches 33 having inclined walls and a tapered profile. In particular, the mold layer 30 may be plasma etched through its entire thickness using a process selective with respect to the nitride material of the sealing layer 27 and the heater material of the cup-shaped heater layer 26. For example, simultaneous chemical and physical etching may be used.

Thus, the microtrench 33 has a sublithographic bottom width and a lithographic top width, which is determined by the thickness of the mold layer 30 and the width of the apertures 32 of the mask 31. By “sublithographic,” it is intended to refer to a dimension that is smaller than what can be formed by lithography, currently 80 nm. By “lithographic,” it is intended to refer to a dimension formed lithographically and thereby having a dimension greater than 80 nm using current technology.

After removing the mask 31, a chalcogenide layer 35 (FIG. 12), for example of Ge₂Sb₂Te₅ with a thickness of 60 nm, is deposited conformally. Thin portions 35a of the chalcogenide layer 35 fill the microtrenches 33 and form phase change regions at the intersection with the cup-shaped heater layer 26. Then, on top of the chalcogenide layer 35, a barrier layer 36, for example of Ti/TiN, and a metal layer 37, for example of AlCu, are deposited and then defined to form bitlines 40. Thus, in the example shown, each bitline 40 includes a stack including an elongated barrier layer 36, metal layer 37, and chalcogenide layer 35.

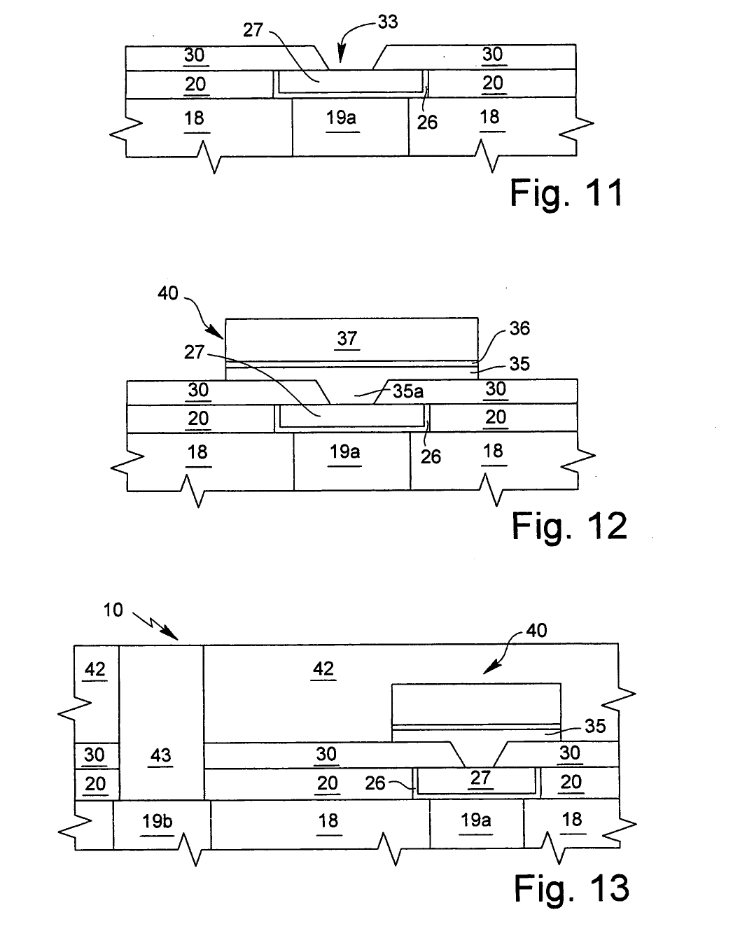

Finally (FIG. 13), a covering layer 42 of dielectric material may be deposited, planarized (for example by CMP) and then opened above the base contacts 19b and above a portion (not shown) of the bit line 40. The openings thus formed may be filled with tungsten to form top contacts 43 to contact the base contacts 19b and the bitlines 40. Then, standard steps may be performed for forming connection lines for connection to the base contacts 19b and to the bitlines 40, forming a passivation and so on.

The described process may ensure precise control of the height of the cup-shaped heater layer 26 and of the thickness of the stop layer 20 in some embodiments. The CMP processes used to planarize the wafer and remove the remaining portions of the first sacrificial layer 21 may be selective with respect to the material of the stop layer. Thereby the resistance of the heater may be controlled in a precise and repeatable way in some embodiments.

The heater (cup-shaped heating layer 26) is surrounded both inside and outside by the same material (e.g., nitride). Thus, the second planarization step (leading to the structure of FIG. 8) stops on a same material around the heating layer 26. Having the same material may ensure a locally homogeneous and planar structure, resulting in good height control in some embodiments. Analogously, the use of the same material inside and outside the heater (stop layer 20 and sealing layer 27) may be advantageous in the etching step that forms the tapered microtrenches 33 since the etching stops on a same material and in a planar way, thereby avoiding the formation of locally asymmetric areas in some cases.

The use of a same material inside and outside the heating layer 26 may be useful during the operation of the phase change memory cell, since the heating layer 26 is surrounded by a same interface. Furthermore, in some embodiments, the use of nitride as stop and sealing material may advantageously reduce any oxidation and deterioration caused by the heater operating at high temperature.

The use of the indicated materials to form the stop layer 20, the sealing layer 27 and the mold layer 30, as well as the use of a selective etch during the formation of the microtrenches 33 may ensure the sealing regions 27 are not damaged during the formation of the microtrenches 33 in some cases.

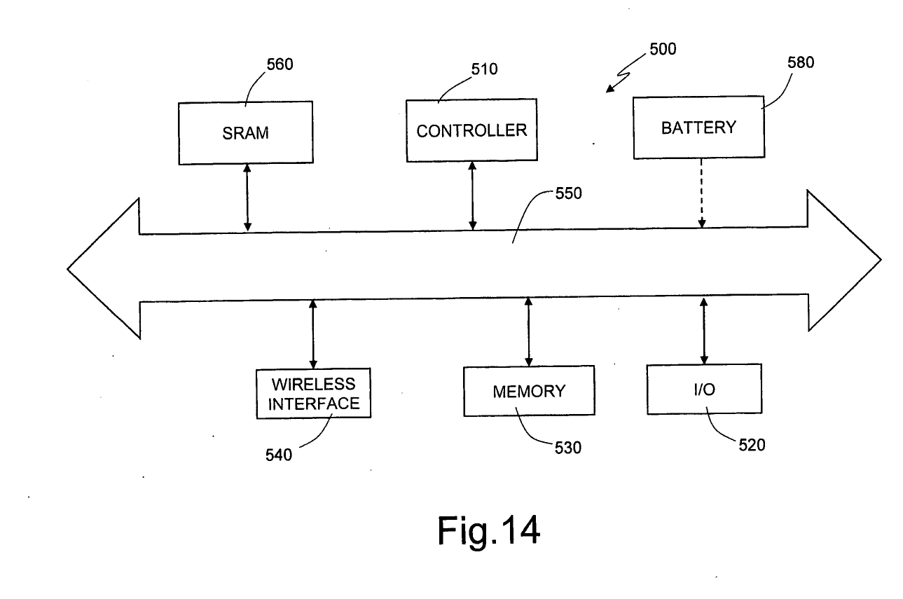

Turning to FIG. 14, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 includes a controller 510, an input/output (I/O) device 520 (e.g. a keypad, display), static random access memory (SRAM) 560, a memory 530, and a wireless interface 540 coupled to each other via a bus 550. A battery 580 is used in some embodiments. It should be noted that the scope of the present invention is not limited to embodiments having any or all of these components.

Controller 510 comprises, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 uses wireless interface 540 to transmit and receive messages to and from a wireless communication network with a radio frequency (RF) signal. Examples of wireless interface 540 may include an antenna or a wireless transceiver, although the scope of the present invention is not limited in this respect.

The same process may be applied to phase change memory devices having a different selector, e.g. of MOS type or an ovonic selector formed over the phase change material. Instead of having a bitline 40 formed by an electrode layer and a phase change layer, the phase change regions and the upper electrode may form by separate “dots” or columns, connected to each other by bitlines.

The sealing layer 27 and of the filling layer 28 may be of the same material, even if this would require a more complicated process.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method for manufacturing a phase change memory cell comprising:
forming a body;
forming a cup-shaped heater element above said body;
forming an etch stop layer over said body;
forming a first sacrificial layer over said stop layer, the first sacrificial layer being of a material that can be etched selectively with respect to said stop layer;
forming an opening in said first sacrificial layer and said stop layer;
forming a heating layer in said opening;
filling said opening with a filling material; and
selectively etching down to said stop layer.

2. The method of claim 1, wherein filling said opening comprises:
forming a sealing layer of the same material as said etch stop layer, partially filling said opening; and
forming a second sacrificial layer of a material different from said etch stop layer.

3. The method of claim 2, including forming said stop layer and said sealing layer of a substantially same thickness.

4. The method of claim 3, including forming said first and second sacrificial layers of the same dielectric material.

5. The method of claim 4, including forming said etch stop layer of silicon nitride and said first and second sacrificial layers of silicon oxide.

6. The method of claim 5, wherein selectively etching comprises removing upper portions of said second sacrificial layer, sealing layer, heating layer, and first sacrificial layer using a first, non-selective chemical/mechanical planarization etch and then removing remaining portions of said first and second sacrificial layers using a second chemical/mechanical planarization etch selective with respect to said etch stop layer.

7. The method of claim 6, wherein forming a tapered phase change region comprises:
forming a mold layer over said stop layer;
plasma etching said mold layer to form a tapered microtrench;
depositing a phase change layer in said tapered microtrench and on said mold layer; and
defining said phase change layer to form a memory region having a tapered portion in contact with said heating layer.

8. The method of claim 7, wherein plasma etching is a simultaneous chemical and physical etching.

9. The method of claim 8, wherein forming a mold layer includes forming a mold layer of at least one of oxide and SiON.

10. The method of claim 7, including etching said mold layer so that said tapered microtrench has a lithographic upper dimension.

11. The method of claim 10, including etching said mold layer so that said microtrench has a sublithographic lower dimension.

12. A phase change memory comprising:
a body;
a first dielectric layer above said body;
a cup-shaped heater element in an opening of said first dielectric layer;
a dielectric region in said cup-shaped heater element;
a second dielectric layer above said first dielectric layer, said second dielectric layer including a microtrench; and
a tapered phase change region in said microtrench in said second dielectric layer, said tapered phase change region crossing said heater element and forming a sublithographic contact area therewith,
wherein the first dielectric layer and said dielectric region are both of silicon nitride.

13. The memory of claim 12, wherein the second dielectric layer is of a material that can be etched selectively with respect to the dielectric region and the first dielectric layer.

14. The memory of claim 13, wherein said second dielectric layer is oxide.

15. The memory of claim 12, wherein said microtrench has a sublithographic lower dimension.

16. The memory of claim 15, wherein said microtrench has a lithographic upper dimension.

17. A system comprising:
a processor;
a static random access memory coupled to said processor; and
a phase change memory coupled to said processor, said phase change memory including a body, a first dielectric layer above said body, a cup-shaped heater element in an opening of said first dielectric layer, a dielectric region is said cup-shaped heater element, a second dielectric layer above said first dielectric layer, said second dielectric layer including a microtrench, and a tapered phase change region in said microtrench in said second dielectric layer, said tapered phase change region crossing said heater element and forming a sublithographic contact area therewith, wherein the first dielectric layer in said dielectric region are both formed of silicon nitride.

18. The system of claim 17, wherein the second dielectric layer is of a material that can be etched selectively with respect to the dielectric region and the first dielectric layer.

19. The system of claim 18, wherein said second dielectric layer is oxide.

20. The system of claim 17, wherein said microtrench has a sublithographic lower dimension.

21. The system of claim 20, wherein said microtrench has a lithographic upper dimension.
